(19) United States
(12) Patent Application Publication
(10) Pub. No.: US 2010/0302790 A1
(43) Pub. Date: Dec. 2, 2010

(54) LED LUMINAIRE AND METHOD FOR FABRICATING THE SAME

(75) Inventor: Wen Jeng Yen, Taipei (TW)

Correspondence Address: LAW OFFICES OF MIKIO ISHIMARU, 333 W. EL CAMINO REAL, SUITE 330, SUNNYVALE, CA, 94087, US

(73) Assignee: ETRONIC TEAM CO., LTD., Taipei (TW)

(21) Appl. No.: 12/533,603

(22) Filed: Jul. 31, 2009

(30) Foreign Application Priority Data
May 27, 2009 (TW) 098117631
Jun. 9, 2009 (TW) 098210221

(51) Int. Cl. F21V 29/00; H01L 21/50

(52) U.S. Cl. 362/373; 438/28; 257/E33.056; 257/E21.499

(57) ABSTRACT

A light emitting diode (LED) luminaire includes: a heat dissipating module having a heat conductive portion and a plurality of heat dissipating fins disposed on the heat conductive portion, the outer surfaces of the heat dissipating fins having a plurality of titanium nanoparticles disposed thereon for increasing the heat dissipating surface area of the heat dissipating fins per unit volume occupied thereby; at least a substrate provided with a plurality of LEDs thereon and disposed on the heat conductive portion so as for the at least a substrate to be opposite the heat dissipating fins; and at least a light-permeable cover disposed on and covering the substrate, the light-permeable cover having a plurality of concave portions to accommodate the LEDs of the substrate, respectively, so as to diffuse light emitted from the LEDs, thereby achieving uniform illumination over a large area.

### CROSS REFERENCE TO RELATED APPLICATION(S)

This application claims the benefit of Taiwan patent application no. 098117631 filed on May 27, 2009, with the Taiwan Intellectual Property Office (TIPO), of which is incorporated for reference in its entirety.

This application claims the benefit of Taiwan patent application no. 098210221 filed on Jun. 9, 2009, with the Taiwan Intellectual Property Office (TIPO), of which is incorporated for reference in its entirety.

### BACKGROUND OF THE INVENTION

1. Field of the Invention

The present invention relates generally to heat dissipating techniques for light emitting diode (LED) luminaires, and more particularly, to an LED luminaire that uses a nano-titanium material to enhance the heat dissipating effect and a fabrication method of the LED luminaire.

2. Description of Related Art

In a conventional street light, the top of an upright pole is bent to form a connecting end so as for a hollow light housing to be connected to the connecting end, allowing at least one lighting element, such as an incandescent lamp or a mercury lamp, to be disposed inside the light housing and a reflect cover to be disposed inside the light housing to thereby reflect light and enhance the illumination effect thereof.

However, the conventional incandescent lamp or mercury lamp has drawbacks, namely high power consumption and short lifetime. By contrast, light emitting diodes (LEDs) consume relatively less power and have long lifetimes and high brightness. Therefore, more and more street lighting products use LEDs as light sources.

However, LEDs generate heat readily and have poor heat resistance. The heat generated by LEDs installed on luminaires overheats circuit boards, the LEDs and power source modules of the LED luminaires, thereby deteriorating or damaging the LED luminaires. To overcome the drawbacks, a heat dissipating module with heat dissipating fins is usually used to dissipate heat generated by LEDs of the LED luminaires and keep the LED luminaires at a low temperature. However, such a heat dissipating module has a quite limited heat dissipating effect. Also, LEDs usually give off linear light beams, which results in low uniformity of illumination of LED luminaires and a narrow illumination range.

Therefore, it is imperative to overcome the above-described drawbacks of the prior art.

### SUMMARY OF THE INVENTION

According to the above drawbacks, the present invention provides a light emitting diode (LED) luminaire and a method for fabricating the same so as to achieve a preferred heat dissipating effect and uniform illumination over a larger area.

In accordance with the present invention, an LED luminaire comprises: a heat dissipating module having a heat conductive portion and a plurality of heat dissipating fins disposed on the heat conductive portion, the outer surfaces of the heat dissipating fins having a plurality of titanium nanoparticles disposed thereon; at least a substrate provided with a plurality of LEDs thereon and disposed on the heat conductive portion so as for the substrate to be opposite the heat dissipating fins; and at least a light-permeable cover disposed on and covering the substrate, the light-permeable cover having a plurality of concave portions for accommodating the LEDs of the substrate respectively.

The LED luminaire can further comprise a waterproof pad disposed between the substrate and the light-permeable cover. The LED luminaire further comprises a casing disposed on the side surface of the heat dissipating module and provided with a power source module therein, and at least an opening is formed on the side surface of the heat dissipating module and penetrated by electric wires for electrically connecting the power source module with the substrate. The LED luminaire further comprises a heat sink paste disposed between the heat dissipating module and the substrate.

The titanium nanoparticles are of a diameter between 1 nm and 100 nm. The light-permeable cover has a light incident surface and a light emitting surface. The light incident surface is defined on the bottom of the concave portions. The light emitting surface is defined on an outer side of the light-permeable cover and is opposite the light incident surface. Therein, the light emitting surface further comprises a plurality of first curved portions and a plurality of second curved portions, each of the first curved portions protrudes outwards and is provided between two corresponding ones of the second curved portions of height gradually increasing in a direction away from the first curved portion.

Further, a method for fabricating an LED luminaire is provided, which comprises: providing a heat dissipating module with a plurality of heat dissipating fins; coating a coating composition on the outer surfaces of the heat dissipating fins, wherein the coating composition comprises a plurality of titanium nanoparticles; and evaporating solvent contained in the coating composition such that the titanium nanoparticles of the coating composition are attached to the outer surfaces of the heat dissipating fins.

Therein, the coating composition comprises 10% to 40% of resin by weight, 2.0% to 20% of titanium nanoparticles by weight, 50% to 8% of solvent by weight, and 5% to 15% of additive by weight. The solvent is a volatile solvent. The titanium nanoparticles are of a diameter between 1 nm and 100 nm. The additive is a dispersing agent, a plasticizer, or a hardening agent.

According to the present invention, the light-permeable cover can diffuse light emitted from the LEDs so as to achieve uniform illumination over a larger area. Meanwhile, the titanium nanoparticles increase the heat dissipating surface area of the heat dissipating fins per unit volume occupied thereby, thus achieving a preferred heat dissipating effect.

### BRIEF DESCRIPTION OF DRAWINGS

FIGS. 1A to 1C are schematic views of a light emitting diode (LED) luminaire according to the present invention, including an oblique view of the LED luminaire (FIG. 1A), an exploded view of the LED luminaire (FIG. 1B), and a partial enlarged view of the LED luminaire (FIG. 1C);

FIGS. 2A to 2C are schematic views of a light-permeable cover of the LED luminaire according to the present invention, including an oblique view of the light-permeable cover (FIG. 2A), a side view of the light-permeable cover (FIG. 2B), and a cross-sectional view of the light-permeable cover taken along a line AA′ of FIG. 2A (FIG. 2C); and

FIG. 3 is a flow diagram showing a method for fabricating an LED luminaire according to the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the specification.

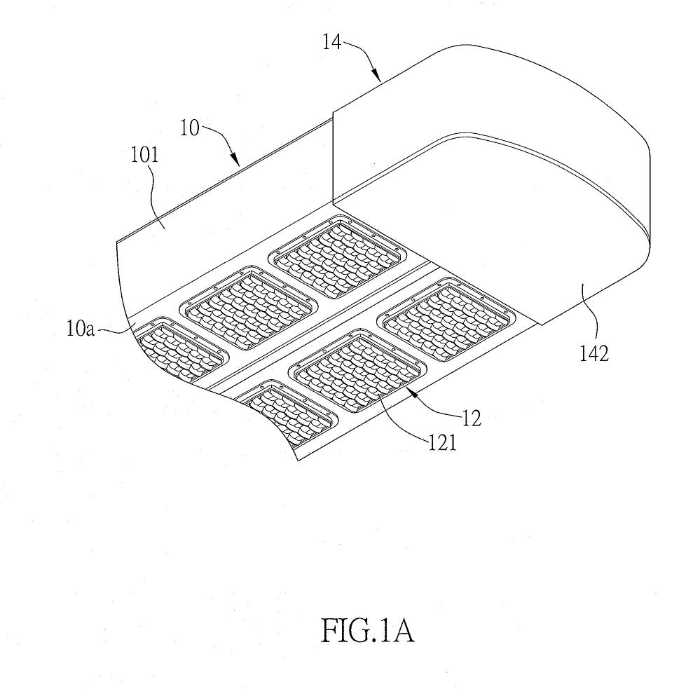

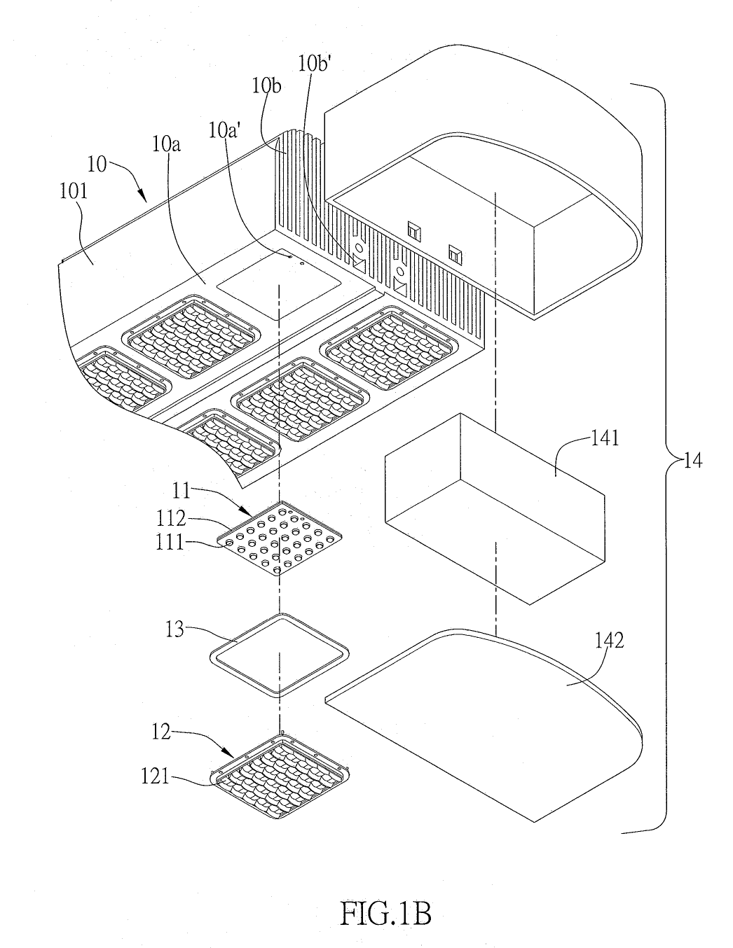

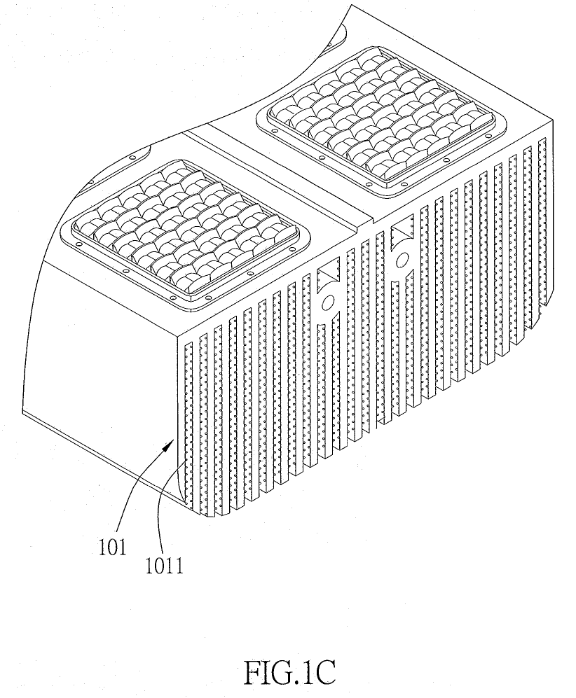

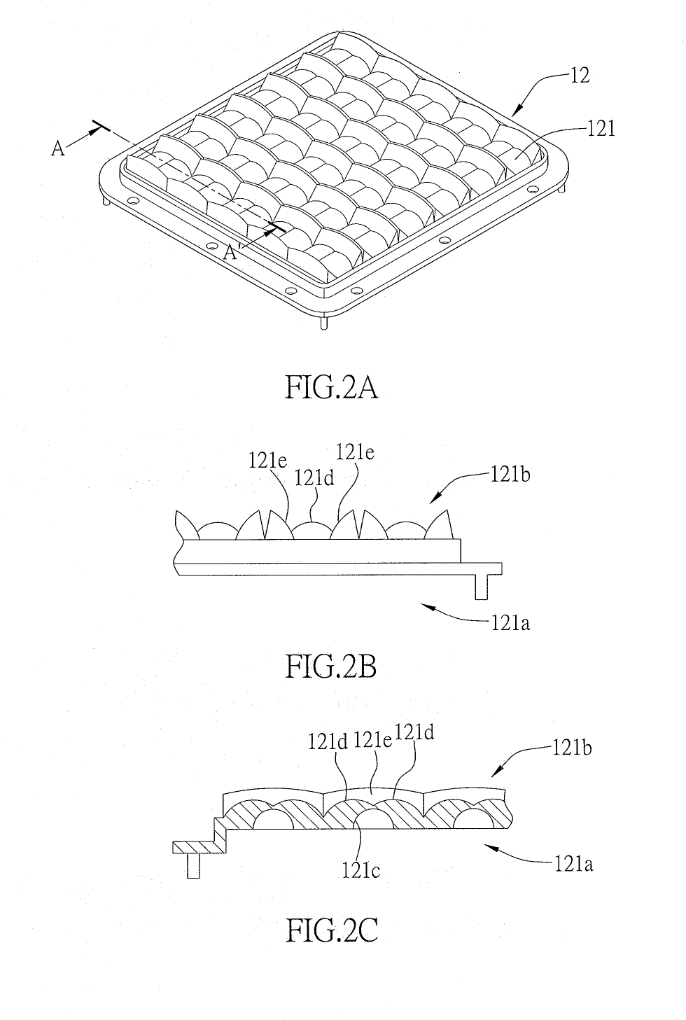

FIGS. 1A to 1C are schematic views of a light emitting diode (LED) luminaire according to the present invention, including an oblique view of the LED luminaire (FIG. 1A), an exploded view of the LED luminaire (FIG. 1B), and a partial enlarged view of the LED luminaire (FIG. 1C). FIGS. 2A to 2C are schematic views of a light-permeable cover of the LED luminaire according to the present invention, including an oblique view of the light-permeable cover (FIG. 2A), a side view of the light-permeable cover (FIG. 2B), and a cross-sectional view of the light-permeable cover taken along a line AA′ of FIG. 2A (FIG. 2C).

Referring to FIGS. 1A to 2C, the LED luminaire according to the present invention comprises: a heat dissipating module 10 having a heat conductive portion 10a and a plurality of heat dissipating fins 101 disposed on the heat conductive portion 10a, the outer surfaces of the heat dissipating fins 101 having a plurality of titanium nanoparticles 1011 disposed thereon; at least a substrate 11 disposed on the heat conductive portion 10a opposite to the heat dissipating fins 101, wherein the substrate 11 has a plurality of LEDs 111 thereon; and at least a light-permeable cover 12 disposed on and covering the substrate 11 and connected to the heat dissipating module 10, wherein the light-permeable cover 12 has a plurality of concave portions 121c for accommodating the LEDs 111 on the substrate 11.

Therein, the substrate 11 is, but is not limited to, a printed circuit board (PCB) or a metal core printed circuit board (MCPCB). The light-permeable cover 12 is made of, but is not limited to, polycarbonate (PC). Alternatively, the light-permeable cover 12 is made of a material having a light-permeable property.

In the present embodiment, the LED luminaire further comprises a waterproof pad 13 made of a silicone material and disposed between the substrate 11 and the light-permeable cover 12. But the present embodiment is not limited thereto. In other embodiments, if the substrate 11 is covered by the light-permeable cover 12 in an airtight manner, the waterproof pad 13 can be dispensed with. Alternatively, the waterproof pad 13 can be replaced by other equivalent materials.

In the present embodiment, the LED luminaire further comprises a casing 14 disposed on the side surface of the heat dissipating module 10 (but is not limited thereto). Alternatively, the casing 14 is disposed at other positions on the heat dissipating module 10. The casing 14 further comprises a power source module 141 provided therein and a bottom plate 142 provided thereunder for supporting the power source module 141 allowing the power source module 141 to be placed inside the casing 14. In addition, at least a first opening 10a′ is formed in the heat conductive portion 10a of the heat dissipating module 10 and at least a second opening 10b′ is formed in the above-mentioned side surface of the heat dissipating module 10. Electric wires (not shown) pass through the first opening 10a′ and the second opening 10b′ so as to electrically connect the power source module 141 with the substrate 11.

In other embodiments, the LED luminaire further comprises a layer of heat sink paste 112 disposed between the heat dissipating module 10 and the substrate 11 so as for heat generated by the LEDs 111 on the substrate 11 to be transferred to the heat dissipating module 10 for heat dissipation.

The heat dissipating module 10 is made of a metal of high thermal conductivity, such as copper or aluminum, which, however, is not limited thereto.

Referring to FIG. 1C, in an embodiment, the titanium nanoparticles 1011 on the outer surfaces of the heat dissipating fins 101 are of a diameter between 1 nm and 100 nm. With the titanium nanoparticles 1011, the heat dissipating area of the heat dissipating fins 101 per unit volume occupied thereby is increased and accordingly the heat dissipating characteristics of the heat dissipating module 10 is improved. In addition, the titanium nanoparticles 1011 can efficiently prevent dust from being attached to the heat dissipating fins 101 that may otherwise adversely affect the overall heat dissipating effect of the heat dissipating module 10.

In the present embodiment, the titanium nanoparticles 1011 are one of the constituents of a coating composition so as to be coated on the heat dissipating fins 101. The coating composition contains at least one selected from the group consisting of 10% to 40% of resin by weight, 2.0% to 20% of titanium nanoparticles 1011 by weight, 50% to 80% of solvent by weight, and 5% to 15% of additive (such as a dispersing agent, plasticizer, or hardening agent) by weight. Therein, the solvent is a volatile solvent, which may be an organic solvent such as methanol, ethanol and acetone, or an inorganic solvent, or water.

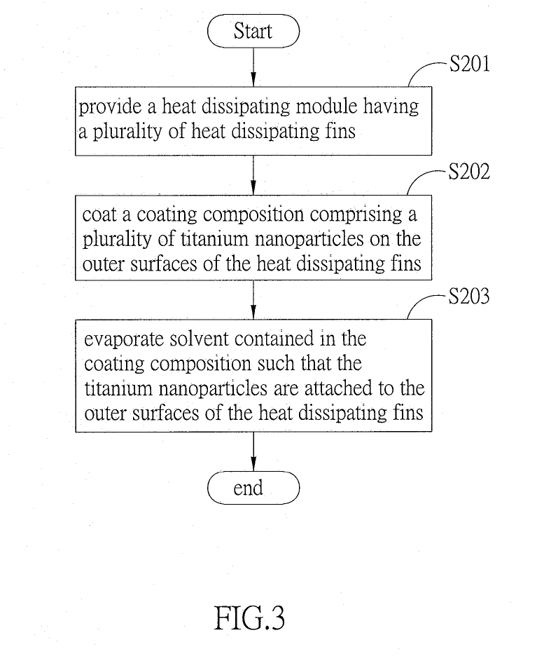

Referring to FIG. 3, a method for disposing nanoparticles on outer surfaces of a heat dissipating module of the LED luminaire according to the present invention is shown. As shown in the drawing, first, at step S201, a heat dissipating module 10 comprising a plurality of heat dissipating fins 101 is provided, wherein the heating dissipating module 10 is made of a metal of high thermal conductivity. Then, the process goes to step S202.

At step S202, the above-described coating composition is coated on the outer surfaces of the heat dissipating fins 101 of the heat dissipating module 10. Then, the process goes to step S203.

At step S203, the solvent contained in the coating composition is evaporated by heat drying or air drying such that the plurality of titanium nanoparticles of the coating composition can be deposited on the outer surfaces of the heat dissipating fins 101, thereby maximizing the heat dissipating surface area of the heat dissipating fins 101 per unit volume so as for heat generated by the LED luminaire to be rapidly dissipated.

It should be noted that the titanium nanoparticles can be replaced by other nano materials with good heat dissipating characteristics, such as titanium dioxide (TiO₂), silicon dioxide (SiO₂), and zinc oxide (ZnO), which however is not limited thereto.

In the above-described LED luminaire, the LEDs 111 are secured in position to the substrate 11 by soldering, using solder made of tin, which, however, is not limited thereto. The heat dissipating module 10, the substrate 11, the light-permeable cover 12 and the waterproof pad 13 are put together by screws but are not limited thereto. In other embodiments, they can also be put together by mortise and tenon joints or by latches.

Referring to FIGS. 2A to 2C, the light-permeable cover 12 is provided with a plurality of lens structures 121 corresponding in position to the LEDs 111, respectively, wherein each of the lens structures 121 has a light incident surface 121a and a light emitting surface 121b. As shown in the drawings, the light incident surface 121a is provided with the concave portions 121c for accommodating the LEDs 111, and the light emitting surface 121b is defined on an outer side of the light-permeable cover 12 and is opposite the light incident surface 121a. Further, the light emitting surface 121b comprises a plurality of first curved portions 121d and a plurality of second curved portions 121e, wherein every two of the first curved portions 121d are arranged protruding outwards and symmetric to each other and disposed between two of the second curved portions 121e, the height of the two second curved portions 121e gradually increasing in a direction extending away from the first curved portions 121d.

The lens structures 121 are use to diffuse linear light beams generated by the LEDs 111 so as to form diffused light beams with uniform brightness, thereby increasing the illumination range of the luminaire. The diffusion angle is, but is not limited to, 60 degrees. The diffusion angle can be adjusted as needed.

It should be noted that the above-described LED luminaire is mainly applicable to street lighting. However, the LED luminaire can also be used for tunnel lighting, indoor or outdoor lighting and so on.

Therefore, according to the present invention, the lens structures diffuse light emitted from the LEDs so as to achieve uniform illumination over a larger area. Meanwhile, the titanium nanoparticles increase the heat dissipating surface area of the heat dissipating fins per unit volume occupied thereby, thus achieving a preferred heat dissipating effect.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A light emitting diode (LED) luminaire, comprising:
a heat dissipating module having a heat conductive portion and a plurality of heat dissipating fins disposed on the heat conductive portion, the heat dissipating fins having outer surfaces with a plurality of titanium nanoparticles disposed thereon;
at least a substrate provided with a plurality of LEDs thereon and disposed on the heat conductive portion so as for the at least a substrate to be opposite the heat dissipating fins; and
at least a light-permeable cover for covering the substrate, the light-permeable cover having a plurality of concave portions for accommodating the LEDs, respectively.

2. The LED luminaire of claim 1, further comprising a waterproof pad disposed between the substrate and the light-permeable cover.

3. The LED luminaire of claim 1, further comprising a casing disposed on a side surface of the heat dissipating module and provided with a power source module therein.

4. The LED luminaire of claim 3, wherein at least an opening is formed on said side surface of the heat dissipating module and penetrated by electric wires for electrically connecting the power source module with the substrate.

5. The LED luminaire of claim 1, further comprising a heat sink paste disposed between the heat dissipating module and the substrate.

6. The LED luminaire of claim 1, wherein the titanium nanoparticles are of a diameter between 1 nm and 100 nm.

7. The LED luminaire of claim 1, wherein the light-permeable cover has a light incident surface defined on a bottom of the concave portions and a light emitting surface defined on an outer side of the light-permeable cover and opposing the light incident surface.

8. The LED luminaire of claim 7, wherein the light emitting surface further comprises a plurality of first curved portions and a plurality of second curved portions, the first curved portions each protruding outwards and being provided between two corresponding ones of the second curved portions of height gradually increasing in a direction away from the first curved portion.

9. A method for fabricating a light emitting diode (LED) luminaire, comprising the steps of:
providing a heat dissipating module provided with a plurality of heat dissipating fins;
coating a coating composition on outer surfaces of the heat dissipating fins, wherein the coating composition comprises a plurality of titanium nanoparticles; and
evaporating solvent contained in the coating composition so as for the titanium nanoparticles of the coating composition to be attached to the outer surfaces of the heat dissipating fins.

10. The method of claim 9, wherein the coating composition contains at least one selected from the group consisting of 10% to 40% of resin by weight, 2.0% to 20% of titanium nanoparticles by weight, 50% to 80% of solvent by weight, and 5% to 15% of additive by weight.

11. The method of claim 10, wherein the solvent is a volatile solvent.

12. The method of claim 10, wherein the titanium nanoparticles are of a diameter between 1 nm and 100 nm.

13. The method of claim 10, wherein the additive is a dispersing agent, a plasticizer, or a hardening agent.
